(19) United States
(12) Patent Application Publication
(10) Pub. No.: US 2026/0113900 A1
(43) Pub. Date: Apr. 23, 2026

(54) HEALTH MONITORING SYSTEM FOR A DIRECT LIQUID COOLING SYSTEM

(71) Applicant: DELL PRODUCTS L.P., Round Rock, TX (US)

(72) Inventor: James Utz, Georgetown, TX (US)

(21) Appl. No.: 18/918,525

(22) Filed: Oct. 17, 2024

(51) Int. Cl. H05K 7/20; G01M 3/26

(52) U.S. Cl. CPC H05K 7/20836; G01M 3/26; H05K 7/20781

(57) ABSTRACT

An information handling system includes a liquid cooling distribution system with a supply line and a return line. The information handling system determines a first amount of current needed to create a first differential temperature value within the supply line. The information handling system further determines a second amount of current needed to create a second differential temperature value with the return line. Based on the first amount of current, the information handling system determines a first cooling liquid flow rate through the supply line. Based on the second amount of current, the information handling system determines a second cooling liquid flow rate through the return line. In response to the first cooling liquid flow rate not being equal to the second cooling liquid flow rate, the system provides a leak detection signal.

### FIELD OF THE DISCLOSURE

The present disclosure generally relates to information handling systems, and more particularly relates to monitoring the health of a direct liquid cooling system.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems.

Information handling systems can also implement various virtualized architectures. Data and voice communications among information handling systems may be via networks that are wired, wireless, or some combination.

### SUMMARY

An information handling system includes a liquid cooling distribution system having a supply line and a return line. The information handling system may determine a first amount of current needed to create a first differential temperature value within the supply line, and further may determine a second amount of current needed to create a second differential temperature value with the return line. Based on the first amount of current, the information handling system may determine a first cooling liquid flow rate through the supply line. Based on the second amount of current, the information handling system may determine a second cooling liquid flow rate through the return line. In response to the first cooling liquid flow rate not being equal to the second cooling liquid flow rate, the system may provide a leak detection signal.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a diagram of a portion of an information handling including a direct liquid cooling system according to at least one embodiment of the present disclosure;

FIGS. 2 and 3 are diagrams of a health monitoring system for a liquid cooling system according to at least one embodiment of the present disclosure;

FIG. 4 is a graphical representation of a relationship between an amount of power provided to a heater and a flow rate through a cooling line of a liquid cooling system according to at least one embodiment of the present disclosure;

FIG. 5 is a flow diagram of a method for monitoring the health of the liquid cooling system of an information handling system according to at least one embodiment of the present disclosure; and

FIG. 6 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

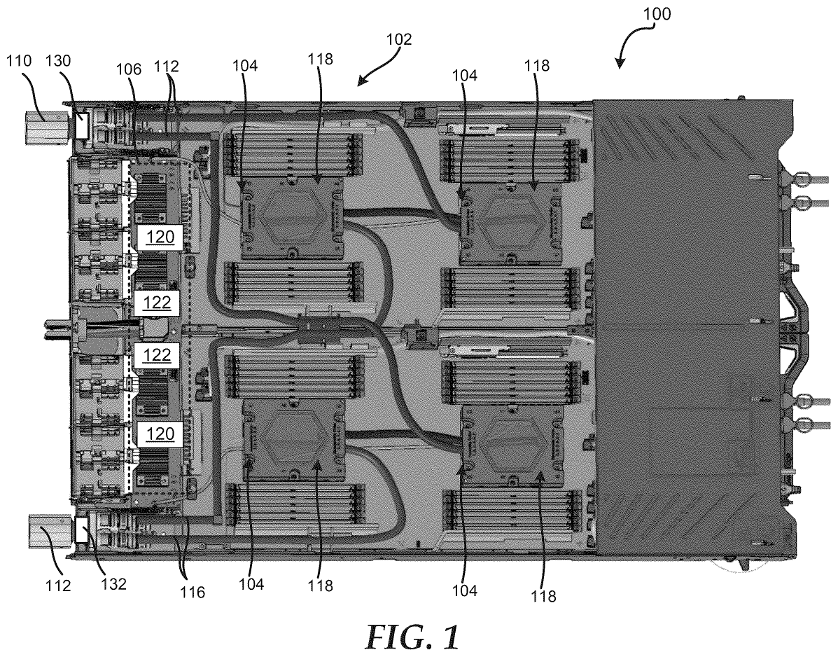

FIG. 1 illustrates an information handling system 100 according to at least one embodiment of the present disclosure. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

Information handling system 100 includes a liquid cooling assembly 102, multiple processors 104, and a power distribution board 106. Liquid cooling assembly 102 includes a coolant supply line coupler 110 and a coolant return line coupler 112, coolant supply lines 114, coolant return lines 116, and multiple cold plates 118. Power distribution board 106 includes any suitable number of components including, but not limited to, multiple power distribution components, multiple computing devices or processors 120. Liquid cooling assembly 102 also includes a coolant supply line health monitoring system 130 and a coolant return line health monitoring system 132. Information handling system 100 and/or liquid cooling assembly 102 may include additional components without varying from the scope of this disclosure.

In certain examples, liquid cooling assembly 102 may be coupled to a pump, which in turn may circulate a coolant such as water or other liquid (e.g., water plus additives) through coolant supply line coupler 110, coolant supply lines 114, cold plates 118, coolant return lines 116, and a coolant return line coupler 112. This circulation of the coolant may provide liquid cooling to multiple components of information handling system 100, including memory, CPUs 104, GPUs, as well as other components. The coolant circulates in a closed loop within the housing of information handling system 100 and absorbs heat from the components to cool the components via cold plates 114. Liquid cooling leverages the exceptional thermal capacity of liquid to absorb and remove heat created by new high-power processors 104. Cold plates 114 may be attached directly to processors 104, enabling the coolant to capture and convey heat to a heat exchanger located, for example, in a rack or row. In a datacenter, for example, the heat load may be removed from the datacenter via a liquid loop, potentially bypassing the expensive chiller system. Replacing or supplementing conventional air-cooling with more-efficient liquid cooling may enhance the operational efficiency of the datacenter.

Notwithstanding the advantages of liquid cooling, there is the possibility that one or more components of the liquid cooling assembly may develop leaks over time due to vibration, thermal cycles, aging, misalignment of heat exchangers or cold plates, or the like. Any leak that exposes the components of the information handling system to liquid can cause corrosion or damage to the circuitry within the housing of information handling system 100. In certain arrangements, a leak occurring in one information handling system also may damage one or more nearby information handling systems if the systems are sufficiently close to one another. For example, a leak may occur in one of multiple servers stacked on a vertical rack (an increasingly common configuration). If the leak is not detected early enough, the coolant may spill out of one server and adversely affect one or more servers below it on the vertical rack. Leak detection within liquid cooling assembly 102 may be improved by the combination of coolant supply line health monitoring system 130 and coolant return line health monitoring system 132 as will be described herein.

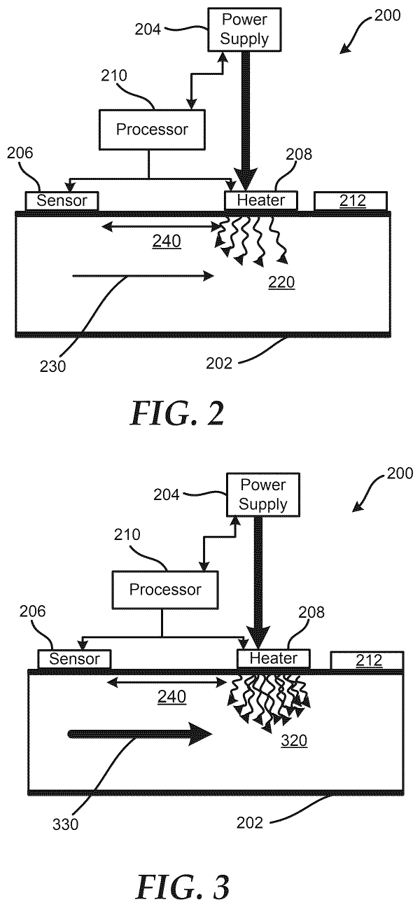

During operation of information handling system 100, liquid cooling assembly 102 may provide the coolant through coolant supply line coupler 110, coolant supply lines 114, cold plates 118, coolant return lines 116, and a coolant return line coupler 112. Health monitoring system 130 may determine the flow rate of the coolant within supply lines 114, and health monitoring system 132 may determine the flow rate of the coolant within supply lines 116. The determination of the flow rate by health monitoring systems 130 and 132 will be described with respect to FIGS. 2 and 3 below.

FIGS. 2 and 3 illustrate a health monitoring system 200 for a liquid cooling assembly, such as liquid cooling assembly 102 of FIG. 1, according to at least one embodiment of the present disclosure. Health monitoring system 200 may be substantially similar to health monitoring systems 130 and 132 of FIG. 1. Health monitoring system 200 includes liquid coolant line 202, power supply 204, sensor 206, heater 208, processor 210, and a pressure transducer 212. In an example, power supply 204 and processor 210 may be located within a power distribution board, such as power distribution board 106. In another example, power supply 204 may be located within a power distribution board, such as power distribution board 106, and processor 210 may be a processor anywhere within an information handling system, such as a baseboard management controller. Sensor 206 and heater 208 may be physically mounted on liquid coolant line 202. In an example, heater 208 may include a sensor. Health monitoring system 200 may include additional components without varying from the scope of this disclosure.

In certain examples, health monitoring system 200 may operate based on any suitable measurement principle. For example, health monitoring system 200 may operate according to an anemometric measuring principle, and more particularly according to a constant temperature anemometry (CTA). This measuring principle may be based on a heated body, which is cooled by convection caused by a liquid flow. Health monitoring system 200 controls heater 208 such that a temperature difference or differential temperature between sensor 206 and the heater remains constant. In an example, if the liquid coolant is water, a predetermined differential temperature may be about 8 Kelvin.

Processor 210 may control power supply 204 to provide a certain power/current to heater 208 such that the constant differential temperature is maintained. In an example, processor 210 may provide a power signal to power supply 204 and the power signal may be any suitable control signal. For example, the power signal may be dependent on the flow rate or velocity of the liquid coolant and the signal may describe a monotonically increasing function. When the liquid coolant is at rest, no heat is transported away from heater 208 and processor 210 may control power supply 204 to reduce the power/current to zero. In certain examples, as the flow velocity or rate increases the heat removal from the location near sensor 206 and heater 208 may also increase. In these situations, processor 210 may control power supply 204 to provide more power/current to heater 208 so that the differential temperature remains constant.

During operation of health monitoring system 200, processor 210 may provide a signal to power supply 204 to indicate an initial amount of current to be provided to heater 208. Based on the signal, power supply 204 may provide the current to heater 208 that is securely attached to cooling line 202. In response to the current, heater 208 may provide an amount 220 of heat into coolant line 202. As illustrated in FIG. 2, amount 220 of heat may radiate out from heater 208 in all directions within the coolant of line 202.

The coolant may flow through line 202 in the direction of arrow 230. In certain examples, amount 220 of heat may decrease as the heat travels away from heater 208 within the coolant. In an example, the flow rate of the coolant in the direction of arrow 230 may affect the amount 220 of the heat that reaches sensor 206. As stated above, heater 208 may include a sensor to determine the amount 220 of heat provided to the coolant at the location of the heater. Processor 210 may receive the amount 220 of the heat provided by heater 208 and the amount of heat detected by sensor 206. Based on these two amounts, processor 210 may determine a temperature difference or differential temperature 240 between sensor 206 and heater 208.

As illustrated by flow arrow 230, sensor 206 may be located upstream from heater 208, such that the coolant travels past the sensor before it reaches the heater. Based on the location of sensor 206 and heater 208, the flow of the coolant may push or distribute some of the heat from heater 208 downstream or away from sensor 206. In this situation, only a portion of the heat within the coolant may be distributed to the sensor. Based on the flow of the coolant and distribution of amount 240 of the heat, a temperature difference may always exist between sensor 206 and heater 208.

After the initial current amount 220 is provided to heater 208, processor 210 may perform any suitable number of operations to determine the flow rate of the coolant through line 202. In an example, processor 210 may utilize the amount of power/current provided to heater 208 and the detected differential temperature 240 to determine the flow rate of the coolant. For example, processor 210 may access a database that correlates power/current to the flow rate based on differential temperature 240 to determine the flow rate within line 202.

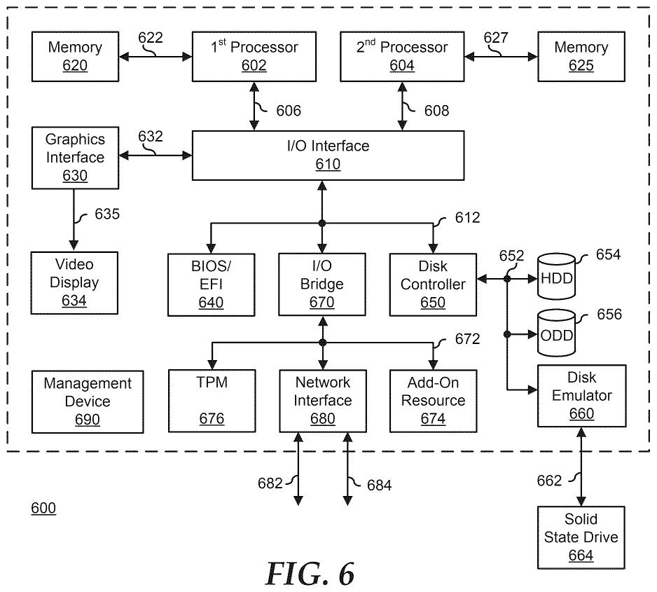

In an example, after processor 210 determines differential temperature 240, the processor may determine whether the differential temperature is equal to a predetermined differential temperature. If the determined differential temperature 240 is equal to the predetermined differential temperature, processor 210 may determine the flow rate within line 202 based on the database that correlates power/current to the flow rate based on the differential temperature 240. Processor 210 may store the flow rate in a memory of the information handling system, such as memory 620 or 625 of information handling system 600 of FIG. 6.

If the determined differential temperature 240 is not equal to the predetermined differential temperature, processor 210 may cause power supply 204 to change the amount of power/current provided to heater 208. In an example, this change of power/current may be repeated until processor 210 determines that the resulting differential temperature 240 is equal to the predetermined differential temperature. At this point, processor 210 may store the flow rate in a memory of the information handling system, such as memory 620 or 625 of information handling system 600 of FIG. 6. In an example, the differential temperature may be any suitable value, such as a very small value that is near zero degrees temperature difference.

Referring now to FIG. 3, arrow 330 is illustrated as bigger thicker than arrow 230 in FIG. 2, which illustratively indicates that the flow rate of coolant in FIG. 3 may be greater than the flow rate of coolant illustrated in FIG. 2. As the flow rate of the coolant increases, the amount 320 provided by heater 208 needs to increase to maintain differential temperature 240 between the heater and sensor 206. After processor 210 causes power supply 222 to provide the initial amount of power/current to heater 208, an amount 320 of heat may be generated by the heater. Processor 210 may receive the temperature values from sensor 206 and heater 208 to determine differential temperature 240. If differential temperature 240 is not equal to the predetermined differential temperature, processor 210 may cause power supply 204 to increase the power/current provided to heater 208 until the differential temperature does equal the predetermined differential temperature.

In an example, based on the flow rate being higher, amount 320 of heat may need to be larger than amount 220 of FIG. 2 as illustrated by the number of arrows in FIG. 3. In this example, processor 210 may control power supply 204 to increase the power/current provided to heater 208 until differential temperature 240 is equal to the predetermined differential temperature. In certain examples, pressure transducer 212 may determine the pressure of coolant within line 202 and provide the pressure to processor 210. In an example, processor 210 may utilize the pressure of the coolant to determine whether a leak is located within a liquid cooling assembly of an information handling system as will be described below.

Referring back to FIG. 1, processor 120 within power distribution board 106 may power signals to multiple power supplies 122 of the power distribution board. In certain examples, the power signals may be different for different power supplies. For example, processor 120 may provide one power signal to one power supply 122 associated with coolant supply line health monitoring system 130 and a different power signal to a power supply associated with coolant return line health monitoring system 132. Based on corresponding power signal, power supply 122 may activate the heater of the corresponding health monitoring system.

Processor 120 may perform operations substantially similar to those described above with respect to processor 210 of FIGS. 2 and 3 to determine flow rates within supply line 114 and return line 116. Based on the determined flow rates, processor 120 may determine whether the flow rate of the coolant in supply line 114 matches the flow rate of the coolant in return line 116. If the flow rates are equal, processor 120 may provide the determined flow rate to the BMC of information handling system 100. Based on receiving the determined flow rate for supply line 114 and return line 116, the BMC may provide this data to a data center associated with the information handling system, to a rack level processor, or the like. In an example, the data center and/or rack level processor may utilize the flow rate data to determine whether liquid cooling assembly 102 in information handling system 100 is operating the same as other liquid cooling assemblies in other information handling system in the server rack.

If the flow rates of supply line 114 and return line 116 are not equal, processor 120 may determine that a leak is located someone within liquid cooling assembly 102. In response to a leak being determined, processor 120 may provide a leak detection notification to the BMC of information handling system 100. In an example, processor 120 may determine the leak based on the flow rate of input liquid cooling line 114 being greater than the flow rate of return liquid cooling line 116. In this example, the decrease in flow rate from supply liquid cooling line 114 to return liquid cooling line 116 may result from a leak somewhere between input coupler 110 and return coupler 112 of liquid cooling assembly 102.

In certain examples, processor 120 may receive pressure measurements from both coolant supply line health monitoring system 130 and coolant return line health monitoring system 132. In an example, small differential pressures between coolant supply line health monitoring system 130 and coolant return line health monitoring system 132 may normal. However, large pressure differences, such as differences that are above a threshold value, may indicate a leak within liquid cooling assembly 102. If an indication of a leak is determined, processor 120 may provide this indication to the BMC of information handling system 100. Based on the leak indication, BMC may perform any suitable operations. For example, the BMC may create and send alerts to one or more individuals associated with information handling system 100. Additionally, BMC may shut down information handling system 100 to prevent or minimize damage to components of the information handling system.

As described above, processor 120 may utilize the pressure measurements and flow rates from coolant supply line health monitoring system 130 and coolant return line health monitoring system 132 to determine whether a leak or other problems may exist in liquid cooling assembly 102. For example, if the pressure in return line 116 is less than the pressure in supply line 114, processor 120 may determine that a blockage or a kink may exist in one or both lines. As described above, differential volumetric flow measurements, such as the flow rate of coolant in supply line 114 being greater than the flow rate of coolant in return line 114, may indicate an internal leak in liquid cooling system 102.

In certain examples, processor 120 may also determine a temperature of the input coolant, and this temperature may be utilized to determine whether rack-level or data center cooling distribution units (CDUs) are working properly. Processor 120 may also utilize the differential temperature measurement and the volumetric flow or flow rate data to perform calculations regarding cooling of components within information handling system 100. For example, this cooling calculations may include, but are not limited to, cooling efficiency, heat energy being removed by the liquid, and heat energy being left behind in the air of information handling system 100. Additionally, BMC of information handling system 100 and BMCs of other information handling system may provide the measurement data to a data center and/or a top of rack processor. In this situation, the data center or top of rack processor may utilize these measurements for all information handling systems, or servers, in a rack or data center to help highlight mis-behaving servers or mis-behaving CDUs. In an example, if liquid cooling assembly 102 is combined with valves, processor 120 may utilize the pressure and flow rate measurements to determine whether valve open and close functions were successful.

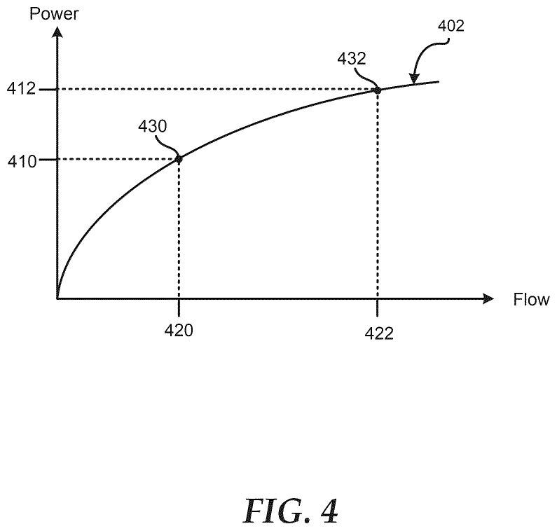

FIG. 4 is a illustrates a graphical representation of a relationship between the amount of power provided to a heater to maintain a particular temperature differential between the heater and a sensor based on a flow rate through a cooling line of a liquid cooling system according to at least one embodiment of the present disclosure.

In an example, line 402 represents a correlation between current/power provided to the heater and a flow rate of the cooling liquid within the coolant lines to maintain the particular or predetermined temperature differential. For example, a first amount of power or current 410 needs to be provided to the heater to maintain the temperature differential when the flow rate of the coolant is a first rate 420, as shown by the intersection at point 430 on line 402. Similarly, a second amount of power or current 412 needs to be provided to the heater to maintain the temperature differential when the flow rate of the coolant is a first rate 422, as shown by the intersection at point 432 on line 402.

Based on this relationship, based on the amount of power or current provided to the heater, a processor, such as processor 120 of FIG. 1, may utilize this relationship to determine the flow rate of the coolant within the associated line. In certain examples, data associated with the relationship between power/current and flow rate may be stored in a memory of the information handling, such as memory 620 or 625 of information handling system 600 of FIG. 6.

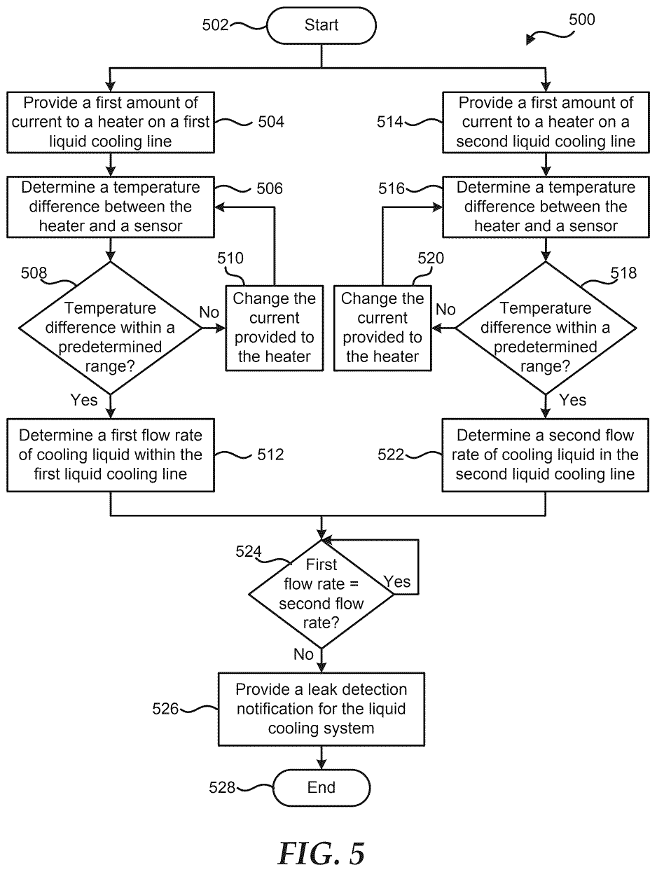

FIG. 5 is a flow diagram of a method 500 for monitoring the health of the liquid cooling system of an information handling system according to at least one embodiment of the present disclosure, starting at block 502. It will be readily appreciated that not every method step set forth in this flow diagram is always necessary, and that certain steps of the methods may be combined, performed simultaneously, in a different order, or perhaps omitted, without varying from the scope of the disclosure. FIG. 5 may be employed in whole, or in part, power supply 204, sensor 206, heater 208, and processor 210 of information handling system 200 in FIG. 2, or any other type of controller, device, module, processor, or any combination thereof, operable to employ all, or portions of, the method of FIG. 5.

In certain examples, the operations of blocks 504, 506, 508, 510, and 512 (504-512) may be performed substantially in parallel with, offset from, or any other possible order with, the operations of blocks 514, 516, 518, 520, and 522 (514-522). For brevity and clarity, the operations of corresponding blocks of 504-512 and the corresponding blocks of 514-522 will be described as being performed in parallel. At blocks 504 and 514, a first amount of current is provided to a heater of a first liquid cooling line. In an example, the first amount of current may be provided from power supply device within a liquid cooling system of an information handling system. Based on the current, the heater may provide a particular amount of heat into a pipe or line of the liquid cooling system.

At blocks 506 and 516, a temperature difference is determined between the heater and a sensor on the pipe. In an example, the heater may not only provide heat to the pipe, but also include a sensor to measure the temperature of a cooling liquid at the heater. The separate sensor connected to the pipe may be upstream from the heater, such that the cooling liquid travels past the sensor before it reaches the heater. Based on the location of the sensor and the heater, the flow of the cooling liquid may push or distribute some of the heat from the heater downstream or away from the sensor. In this situation, only a portion of the heat within the cooling liquid will be distributed to the sensor. Based on the flow of the cooling liquid and distribution of the heat, a temperature difference will always exist between the sensor and the heater.

At blocks 508 and 518, a determination is made whether the temperature difference is within a predetermined temperature range. In an example, the predetermined temperature range may be based on an expected flow rate within the pipes of the liquid cooling system. The expected flow rate may be the rate at which the cooling liquid travels through the liquid cooling system to provide a needed amount of thermal dissipation.

If the temperature difference is not within the predetermined range, an amount of current provided to the heater is changed at blocks 510 and 520, and the respective flow diagrams continue as stated above of corresponding blocks 506 and 516. When the temperature difference is within the predetermined range, a flow rate of the cooling liquid within an input liquid cooling line is determined at block 512 and a flow rate of the cooling liquid within the return liquid cooling line is determined at block 522.

At block 524, a determination is made whether the first flow rate is substantially equal to the second flow rate. If the flow rates are equal, the flow diagram continues as stated above at blocks 504 and 514. If the flow rates are not equal, a leak detection notification is provided at block 526 and the flow diagram ends at block 528. In an example, the leak may be determined based on the flow rate of the input liquid cooling line being greater than the flow rate of the return liquid cooling line. In this example, the decrease in flow rate from the supply liquid cooling line to the return liquid cooling line may result from a leak somewhere in the liquid cooling line from the input to the return.

FIG. 6 shows a generalized embodiment of an information handling system 600 according to an embodiment of the present disclosure. Information handling system 600 may be substantially similar to information handling system 100 of FIG. 1. Information handling system 600 can include devices or modules that embody one or more of the devices or modules described below and operates to perform one or more of the methods described below.

Information handling system 600 includes a processors 602 and 604, an input/output (I/O) interface 610, memories 620 and 625, a graphics interface 630, a basic input and output system/universal extensible firmware interface (BIOS/UEFI) module 640, a disk controller 650, a hard disk drive (HDD) 654, an optical disk drive (ODD) 656, a disk emulator 660 connected to an external solid state drive (SSD) 664, an I/O bridge 670, one or more add-on resources 674, a trusted platform module (TPM) 676, a network interface 680, a management device 690, and a power supply 695. Processors 602 and 604, I/O interface 610, memory 620, graphics interface 630, BIOS/UEFI module 640, disk controller 650, HDD 654, ODD 656, disk emulator 660, SSD 664, I/O bridge 670, add-on resources 674, TPM 676, and network interface 680 operate together to provide a host environment of information handling system 600 that operates to provide the data processing functionality of the information handling system. The host environment operates to execute machine-executable code, including platform BIOS/UEFI code, device firmware, operating system code, applications, programs, and the like, to perform the data processing tasks associated with information handling system 600.

In the host environment, processor 602 is connected to I/O interface 610 via processor interface 606, and processor 604 is connected to the I/O interface via processor interface 608. Memory 620 is connected to processor 602 via a memory interface 622. Memory 625 is connected to processor 604 via a memory interface 627. Graphics interface 630 is connected to I/O interface 610 via a graphics interface 632 and provides a video display output 636 to a video display 634. In a particular embodiment, information handling system 600 includes separate memories that are dedicated to each of processors 602 and 604 via separate memory interfaces. An example of memories 620 and 630 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 640, disk controller 650, and I/O bridge 670 are connected to I/O interface 610 via an I/O channel 612. An example of I/O channel 612 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 610 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 640 includes BIOS/UEFI code operable to detect resources within information handling system 600, to provide drivers for the resources, initialize the resources, and access the resources. BIOS/UEFI module 640 includes code that operates to detect resources within information handling system 600, to provide drivers for the resources, to initialize the resources, and to access the resources.

Disk controller 650 includes a disk interface 652 that connects the disk controller to HDD 654, to ODD 656, and to disk emulator 660. An example of disk interface 652 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 660 permits SSD 664 to be connected to information handling system 600 via an external interface 662. An example of external interface 662 includes a USB interface, an IEEE 4394 (Firewire) interface, a proprietary interface, or a combination thereof. Alternatively, solid-state drive 664 can be disposed within information handling system 600.

I/O bridge 670 includes a peripheral interface 672 that connects the I/O bridge to add-on resource 674, to TPM 676, and to network interface 680. Peripheral interface 672 can be the same type of interface as I/O channel 612 or can be a different type of interface. As such, I/O bridge 670 extends the capacity of I/O channel 612 when peripheral interface 672 and the I/O channel are of the same type, and the I/O bridge translates information from a format suitable to the I/O channel to a format suitable to the peripheral channel 672 when they are of a different type. Add-on resource 674 can include a data storage system, an additional graphics interface, a network interface card (NIC), a sound/video processing card, another add-on resource, or a combination thereof. Add-on resource 674 can be on a main circuit board, on separate circuit board or add-in card disposed within information handling system 600, a device that is external to the information handling system, or a combination thereof.

Network interface 680 represents a NIC disposed within information handling system 600, on a main circuit board of the information handling system, integrated onto another component such as I/O interface 610, in another suitable location, or a combination thereof. Network interface device 680 includes network channels 682 and 684 that provide interfaces to devices that are external to information handling system 600. In a particular embodiment, network channels 682 and 684 are of a different type than peripheral channel 672 and network interface 680 translates information from a format suitable to the peripheral channel to a format suitable to external devices. An example of network channels 682 and 684 includes InfiniBand channels, Fibre Channel channels, Gigabit Ethernet channels, proprietary channel architectures, or a combination thereof. Network channels 682 and 684 can be connected to external network resources (not illustrated). The network resource can include another information handling system, a data storage system, another network, a grid management system, another suitable resource, or a combination thereof.

Management device 690 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 600. In particular, management device 690 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 600, such as system cooling fans and power supplies. Management device 690 can include a network connection to an external management system, and the management device can communicate with the management system to report status information for information handling system 600, to receive BIOS/UEFI or system firmware updates, or to perform other task for managing and controlling the operation of information handling system 600.

Management device 690 can operate off of a separate power plane from the components of the host environment so that the management device receives power to manage information handling system 600 when the information handling system is otherwise shut down. An example of management device 690 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 690 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. An information handling system comprising:
a liquid cooling distribution system including a supply line and a return line; and
a processor to communicate with the liquid cooling distribution system, the processor to:
determine a first amount of current needed to create a first differential temperature value within the supply line;
determine a second amount of current needed to create a second differential temperature value with the return line;
based on the first amount of current, determine a first cooling liquid flow rate through the supply line;
based on the second amount of current, determine a second cooling liquid flow rate through the return line; and
in response to the first cooling liquid flow rate not being equal to the second cooling liquid flow rate, provide a leak detection signal.

2. The information handling system of claim 1, wherein in response to the first cooling liquid flow rate being equal to the second cooling liquid flow rate, the processor further to provide the first and second cooling liquid flow rate to a control node of a server rack.

3. The information handling system of claim 1, wherein the determination of the first amount of current, the processor further to: change a current associated with the supply line until the first differential temperature value is reached.

4. The information handling system of claim 3, wherein the first amount of current increases as the first cooling liquid flow rate increases to maintain the first differential temperature value within the supply line.

5. The information handling system of claim 1, wherein the processor further to: determine the first differential temperature value between first and second points on the supply line.

6. The information handling system of claim 5, wherein the first point is a location that the first amount of current is provided and the second point is upstream from the first point.

7. The information handling system of claim 1, wherein the processor is located within a power distribution board of the information handling system.

8. A method comprising:
determining, by an information handling system, a first amount of current needed to create a first differential temperature value within a supply line of a liquid cooling system;
determining a second amount of current needed to create a second differential temperature value with a return line of the liquid cooling system;
based on the first amount of current, determining a first cooling liquid flow rate through the supply line;
based on the second amount of current, determining a second cooling liquid flow rate through the return line; and
in response to the first cooling liquid flow rate not being equal to the second cooling liquid flow rate, providing, by the processor, a leak detection signal.

9. The method of claim 8 further comprising: in response to the first cooling liquid flow rate being equal to the second cooling liquid flow rate, providing the first and second cooling liquid flow rate to a control node of a server rack.

10. The method of claim 8 wherein the determining of the first amount of current, the method further comprises: changing a current provided to a heater until the first differential temperature value is reached.

11. The method of claim 10, wherein the first amount of current increases as the first cooling liquid flow rate increases to maintain the first differential temperature value.

12. The method of claim 10 where in the heater is in physical communication with the supply line.

13. The method of claim 12, further comprising: determining the first differential temperature value between the heater and a sensor.

14. The method of claim 13, wherein the sensor is located upstream from the heater.

15. The method of claim 8, wherein the processor is located within a power distribution board of the information handling system.

16. An information handling system comprising:
a liquid cooling distribution system including:
a supply line;
a first heater in physical communication with the supply line;
a first sensor in physical communication with the supply line;
a return line;
a second heater in physical communication with the return line; and
a second sensor in physical communication with the return line; and
a processor to:
determine a first amount of current needed to create a first differential temperature value within the supply line;
determine a second amount of current needed to create a second differential temperature value with the return line;
based on the first amount of current, determine a first cooling liquid flow rate through the supply line;
based on the second amount of current, determine a second cooling liquid flow rate through the return line; and
in response to the first cooling liquid flow rate not being equal to the second cooling liquid flow rate, provide a leak detection signal.

17. The information handling system of claim 16, wherein in response to the first cooling liquid flow rate being equal to the second cooling liquid flow rate, the processor further to provide the first and second cooling liquid flow rate to a control node of a server rack.

18. The information handling system of claim 16, wherein the determination of the first amount of current, the processor further to: change a current associated with the supply line until the first differential temperature value is reached.

19. The information handling system of claim 18, wherein the first amount of current increases as the first cooling liquid flow rate increases to maintain the first differential temperature value within the supply line.

20. The information handling system of claim 16, wherein the first sensor is upstream from the first heater.
